(19) United States
(12) Patent Application Publication
(10) Pub. No.: US 2026/0362788 A1
(43) Pub. Date: Nov. 12, 2026

(54) TRANSISTOR WITH SECTIONED SOURCE CONTACT FOR IMPROVED DIODE PERFORMANCE

(71) Applicant: Microchip Technology Incorporated, Chandler, AZ (US)

(72) Inventors: Yogesh Sharma, Colorado Springs, CO (US); Shesh Pandey, Gilbert, AZ (US)

(73) Assignee: Microchip Technology Incorporated, Chandler, AZ (US)

(21) Appl. No.: 19/269,731

(22) Filed: Jul. 15, 2025

Related U.S. Application Data
(60) Provisional application No. 63/803,476, filed on May 9, 2025.

(51) Int. Cl. H10D 84/00; H10D 8/00; H10D 8/01; H10D 30/01; H10D 30/66; H10D 64/62

(52) U.S. Cl. CPC H10D 84/143; H10D 8/045; H10D 8/411; H10D 30/0291; H10D 30/66; H10D 64/62

(57) ABSTRACT

A transistor comprising a substrate comprising a P-type region and an N-type region within a doped well; and a source contact comprising a first section comprising a first metal over at least a portion of the P-type region; and a second section comprising a second metal over at least a portion of the N-type region.

### CROSS-REFERENCE TO RELATED APPLICATION

The present application claims priority to U.S. Provisional Patent Application No. 63/803,476, filed on May 9, 2025, the contents of which are hereby incorporated by reference in their entirety.

### TECHNICAL FIELD

The present disclosure relates generally to power semiconductor devices, and more specifically to a transistor with a sectioned source contact for improved diode performance.

### BACKGROUND

A power semiconductor device is an electronic component to efficiently and reliably control and convert electrical power at relatively high voltages and currents. Unlike regular signal-level semiconductors used in low-power applications, in some instances power semiconductor devices may be optimized for switching and amplifying large amounts of energy. Power semiconductor devices may be used in a variety of applications, such as motor drives, power supplies, renewable energy systems, electric vehicles, and the like.

### SUMMARY OF THE INVENTION

Aspects provide a transistor with a sectioned source contact for improved diode performance.

In one aspect, a transistor comprises a substrate comprising a P-type region and an N-type region within a doped well; and a source contact comprising a first section comprising a first metal over at least a portion of the P-type region; and a second section comprising a second metal over at least a portion of the N-type region.

In another aspect, a method for forming a transistor comprises forming a doped well within a substrate; forming a P-type region and an N-type region within the doped well; and forming a source contact, the source contact comprising a first section comprising a first metal over at least a portion of the P-type region; and a second section comprising a second metal over at least a portion of the N-type region.

In yet another aspect, an apparatus comprises a semiconductor device package comprising a transistor, the transistor comprising a substrate comprising a P-type region and an N-type region within a doped well; and a source contact comprising a first section comprising a first metal over at least a portion of the P-type region; and a second section comprising a second metal over at least a portion of the N-type region.

### BRIEF DESCRIPTION OF THE DRAWINGS

FIG. 1 illustrates a planar metal-oxide-semiconductor field-effect transistor (MOSFET) with sectioned source contacts, in accordance with any of the examples disclosed herein.

FIG. 2 illustrates a body diode of the MOSFET of FIG. 1, in accordance with any of the examples disclosed herein.

FIG. 3 illustrates another planar MOSFET with sectioned source contacts, in accordance with any of the examples disclosed herein.

FIG. 4 illustrates a split gate planar MOSFET with sectioned source contacts, in accordance with any of the examples disclosed herein.

FIGS. 5A-5D illustrates a flow for manufacturing a transistor with sectioned source contacts for improved body diode performance, in accordance with any of the examples disclosed herein.

FIG. 6 illustrates a system comprising a semiconductor device package comprising a transistor with sectioned source contacts for improved diode performance, in accordance with any of the examples disclosed herein.

### DETAILED DESCRIPTION

In various systems, a transistor may include a structure suitable to allow the transistor to be used as a diode. For example, in a power planar metal-oxide-semiconductor field-effect transistor (MOSFET), an intrinsic body diode may exist between the drain and source of the MOSFET. The source of the MOSFET may function as the anode of the diode and the drain may function as the cathode. The diode may conduct current when the MOSFET is reverse-biased (e.g., the source is at a higher potential than the drain). As another example, a bipolar junction transistor (BJT) may be used as a diode when the base-emitter junction is forward-biased. In some instances, a transistor may be used as a diode intentionally within a larger circuit (e.g., an H-bridge, synchronous buck converter, or motor driver).

When operating as a transistor, the resistance associated with a particular terminal (e.g., a source terminal) that alternatively acts as an anode when the transistor is functioning as a diode may generally be inconsequential, as a substantial majority of the resistance of the current path is in the channel and the drift portion of the substrate. However, when operating as a diode, the resistance associated with this terminal may materially affect the diode operation as it makes up a large portion of the resistance from the anode to the cathode.

Various examples of the present disclosure provide transistors with sectioned source contacts for improved diode performance. In order to reduce the resistance of the contact (e.g., a source contact), a first section of the source contact comprises a first conductive material and a second section of the source contact comprises a second conductive material. The conductive materials may be selected based on the characteristics of the portion of the substrate that interfaces with the respective sections. For example, a first section of the source contact that interfaces with a P-doped region of the substrate may comprise a first material (e.g., one or more of aluminum or titanium) while a second section of the source contact that interfaces with an N-doped region of the substrate may comprise a second material (e.g., one or more of nickel, titanium, or vanadium). The particular material utilized may decrease the barrier heights where the respective sections interface with differently doped portions of the substrate and in some instances may result in ohmic contacts at each interface. The improved source contact interfaces may result in decreased source contact resistance relative to architectures that have the same conductive material across the entire source contact.

Various examples disclosed herein may provide one or more technical advantages, such as one or more of a reduced footprint (e.g., since in some instances the circuit does not include a separate diode, such as a Schottky barrier diode), reduced contact resistance, or increased current capacity.

In various examples, the transistor is a power semiconductor device. A power semiconductor device may include any suitable semiconductor device that can accommodate high voltage (e.g., between 10V-8000V, but not limited thereto) applied to one or more terminals or high current (e.g., between 5A-1000A, but not limited thereto) flowing through one or more terminals. In some examples, the transistor is the only semiconductor device formed on the substrate of a die.

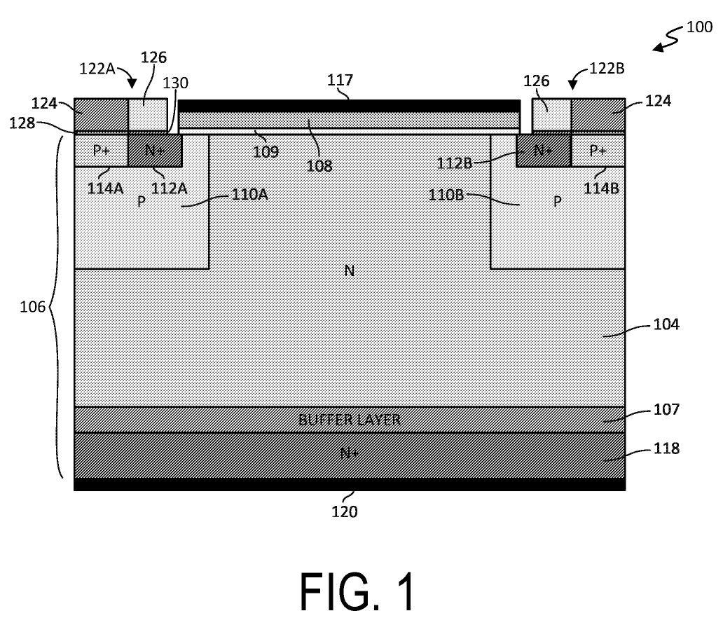

FIG. 1 illustrates a planar metal-oxide-semiconductor field-effect transistor (MOSFET) 100 with sectioned source contacts, in accordance with any of the examples disclosed herein. In this example, the MOSFET 100 is formed on an N-type substrate 106, such as a substrate comprising doped silicon, silicon carbide, or other suitable semiconductor. In other examples, the transistor may be formed on a P-type substrate (e.g., with the polarities of the various regions shown being reversed).

The substrate 106 includes a drift region 104 that is N-type. The substrate 106 also includes a pair of source regions, including P-type regions (e.g., P-wells 110A and 110B) formed in the substrate 106. The source regions also include N-type regions (e.g., N+ regions 112A and 112B) and P-type regions (e.g., P+ regions 114A and 114B) formed respectively within the P-wells 110A and 110B. The pair of source regions may collectively function as the source of the MOSFET 100.

The MOSFET 100 comprises a planar gate 108 (e.g., the gate may have a larger dimension in the lateral direction than the vertical direction). The gate 108 may comprise a conductive material, such as (e.g., heavily doped) polycrystalline silicon. Gate contact 117 may be on top of the gate 108 and may comprise one or more conductive materials, such as aluminum, copper, other metal, metal alloy, or other conductive material.

A gate oxide 109 may be formed between the gate 108 and the substrate 106. For example, the gate oxide may be formed on portions of the N+ regions 112A and 112B, the P-wells 110A and 110B, or the drift region 104. In various examples, the gate oxide 109 may comprise silicon dioxide, hafnium oxide (e.g., with a high k value), or other suitable oxide.

The substrate 106 also includes a buffer layer 107 and an N+ region 118. In the example depicted, the buffer layer 107 is below the drift region 104 and in between the drift region 104 and the N+ region 118. The N+ region 118 may be in contact with a drain contact 120 (e.g., that is below the N+ region 118). The drain contact 120 may comprise one or more conductive materials, such as aluminum, copper, other metal, metal alloy, or other conductive material.

A first source contact 122A of the MOSFET 100 is formed over the N+ region 112A and P+ region 114A. A second source contact 122B is formed over the N+ region 112B and the P+ region 114B. Each source contact 122 includes a first section 124 and a second section 126. The first section 124 is formed over at least a portion (e.g., a majority of the top surface) of a P+ region 114 and the second section 126 is formed over at least a portion (e.g., a majority of the top surface) of an N+ region 112. In some examples, a portion of a first section 124 (e.g., that is closest to the gate 108) may be over a small portion of an N+ region 112 (e.g., that is furthest from the gate 108) or a portion of a second section 126 (e.g., that is furthest from the gate 108) may be over a small portion of a P+ region 114 (e.g., that is closest to the gate 108). In various examples, a portion of the first section 124 (e.g., that is closest to gate 108) may be formed over a portion of the second section 126 (e.g., that is furthest from the gate 108 and has a thickness in the vertical direction that is smaller than other portions of the second section 126) or vice versa.

In some examples, a P+ region 114 has substantially the same width as its adjacent N+ region 112, though in other examples their widths may be different. In some examples (and as depicted), the first section 124 is wider than its adjacent second section 126. In other examples, the first section 124 has substantially the same width as its adjacent second section 126. In yet other examples, the second section 126 is wider than the first section 124.

The width of the second section 126 may be designed such that a gap is present between the second section 126 and the adjacent edges of the gate contact 117, gate 108, and gate oxide 109. Thus, when the gate oxide 109 overlaps onto an N+ region 112, the second section is over only a portion of the N+ region 112 so as to preserve such a gap.

A first section 124 may have a different elemental composition than the second section 126. In a first example, a first section 124 may include a metal or metal alloy comprising one or both of aluminum or titanium, while a second section 126 may include a metal or metal alloy comprising one or more of nickel, titanium, or vanadium. Any other suitable metals or other materials may be used for either section (e.g., metals or materials that result in ohmic contacts at the respective interfaces between the respective sections and the N+ regions 112 or P+ regions 114).

In some examples, a first section 124 comprises a metal alloy comprising aluminum and titanium. In various examples, the thickness (e.g., in the vertical direction) of a first section 124 is between 100 and 300 nanometers (although other examples are not limited thereto). In one example, the alloy of a first section 124 is over 50 % aluminum and less than 50 % titanium (e.g., by volume or by atomic ratio), but any suitable range is contemplated herein. For example, the alloy of the first section 124 may be about 70 % aluminum and 30 % titanium (e.g., by volume or by atomic ratio).

In some examples, a second section 126 comprises a metal alloy comprising nickel and vanadium. In various examples, the thickness (e.g., in the vertical direction) of a second section 126 is between 100 and 300 nanometers. In one example, the alloy of a second section 126 is predominately (e.g., greater than 90 %) nickel and less than 10 % vanadium (by volume or atomic ratio), but any suitable range of compositions is contemplated herein.

In some examples (including the one depicted in FIG. 1), the interfaces between the first sections 124 and the P+ regions 114 include silicide layers 128. Similarly, the interfaces between the second sections 126 and the N+ regions 112 include silicide layers 130. The silicide layers may be relatively thin compared to the thickness of the sections 124 and 126. In other examples, the silicide layers may be omitted, and the sections of the source contacts may contact the substrate directly.

In some examples, silicide layer 128 comprises titanium, silicon, and carbon (e.g., Ti₃SiC₂) and results in an ohmic contact between a first section 124 and a P+ region 114. In various examples, silicide layer 130 comprises nickel and silicon (e.g., Ni₂Si) and results in an ohmic contact between a second section 126 and an N+ region 112. In some examples, silicide layer 128 or silicide layer 130 may comprise titanium and silicon (e.g., TiSi₂).

In various examples, one or more of the drain contact 120, a first section 124 or second section 126 of a source contact 122, or a gate contact 117 may comprise the same conductive material(s). In some examples, any two or more of these may have different compositions.

In various examples, the drift region 104 is lightly doped, the buffer layer 107 is more heavily doped than the drift region 104, and the N+ region 118 is more heavily doped than the buffer layer 107. The N+ region 112 may also be more heavily doped than the drift region 104 and the buffer layer 107. In some instances, the N+ region 118 may be doped at a similar level as N+ region 112 (in other examples, the doping levels may differ). In various examples, the P+ region 114 is more heavily doped than the P-wells 110.

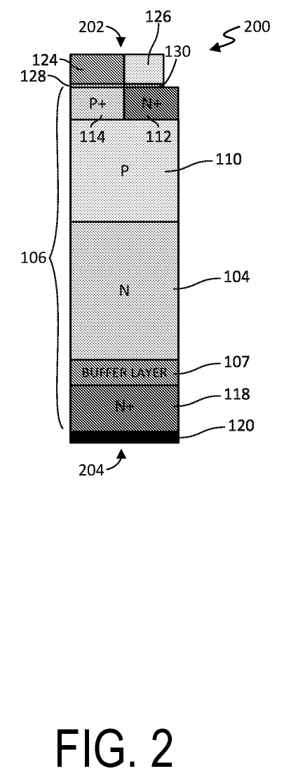

FIG. 2 illustrates a body diode 200 of the MOSFET 100 of FIG. 1, in accordance with any of the examples disclosed herein. A portion of the MOSFET 100 may form the body diode 200. The anode 202 of the body diode 200 is formed by the sections 124 and 126 of a source contact and the cathode 204 is formed by the drain contact 120. A similar body diode may be formed on the other side of the MOSFET 100 through the other source contact. When a sufficient potential is present between the anode 202 and the cathode 204, the transistor may function as a diode, with current flowing from the anode 202 to the cathode 204. This body diode benefits significantly from the reduced contact resistance (relative to a body diode with the same conductive material for the contact over the P+ region 114 and N+ region 112) as current flows through section 124 and P+ region 114 as well as from section 126 through N+ region 112 towards the cathode 204.

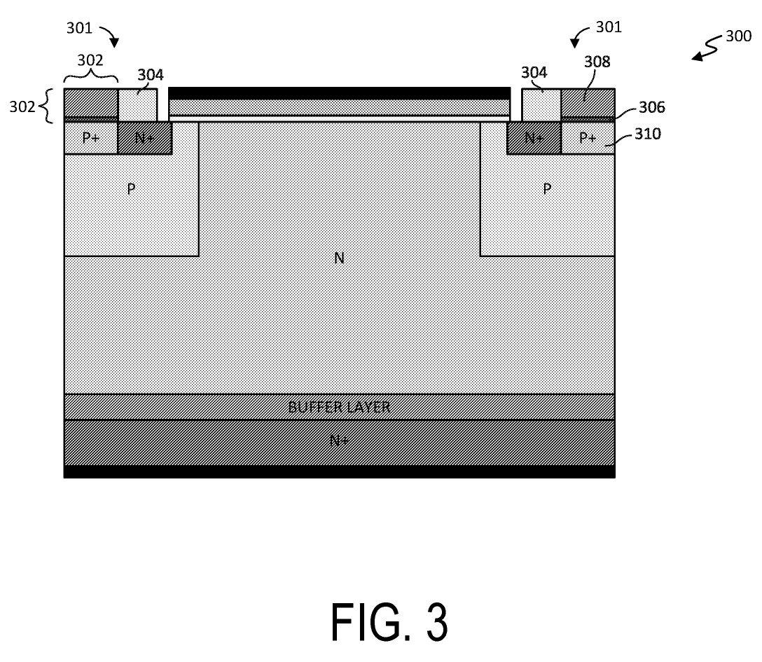

FIG. 3 illustrates another planar MOSFET 300 with sectioned source contacts 301, in accordance with any of the examples disclosed herein. In this example, respective source contacts 301 include a first section 302 and a second section 304. The first section 302 of the respective source contacts 301 includes a bottom layer 306 predominately comprising titanium (e.g., greater than 90 % by volume) and a top layer 308 predominately comprising aluminum (e.g., greater than 90 % by volume). Although not shown, in some examples, a silicide may also be formed between the bottom layer 306 and the P+ region 310.

The first section 302 may have any suitable attributes described herein with respect to other first sections (e.g., first section 124), while the second section 304 may have any suitable attributes described herein with respect to other second sections (e.g., second section 126).

In other examples, respective silicide layers may be present between the second sections 304 and the N+ regions or between the bottom layers 306 and the P+ regions.

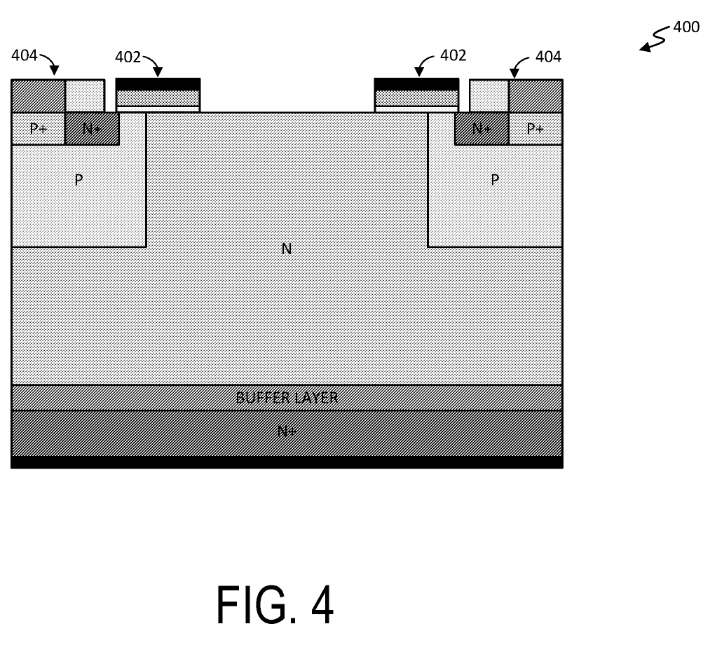

FIG. 4 illustrates a split gate planar MOSFET 400 with sectioned source contacts, in accordance with any of the examples disclosed herein. In this example, the MOSFET 400 includes two discrete gate regions 402 (with gates, gate contacts, and gate oxides). The source contacts 404 may include any suitable characteristics of the other source contacts described herein.

In this example depicted, the different sections of the source contacts 404 contact the P+ regions and N+ regions directly (e.g., instead of through a silicide). In other examples, silicide layers may be present at the interfaces of the source contacts 404 with the substrate.

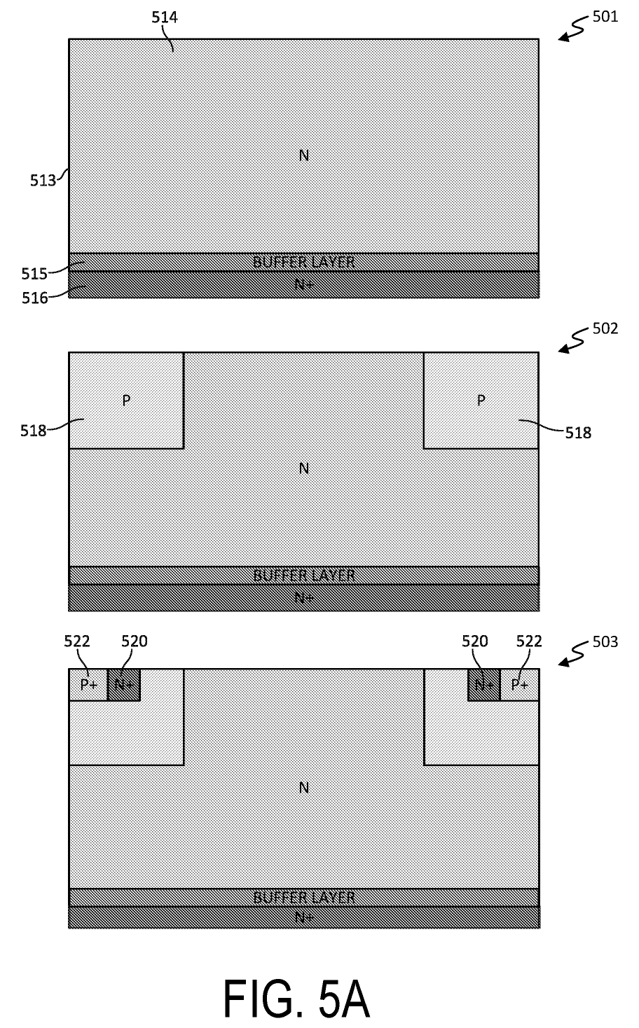

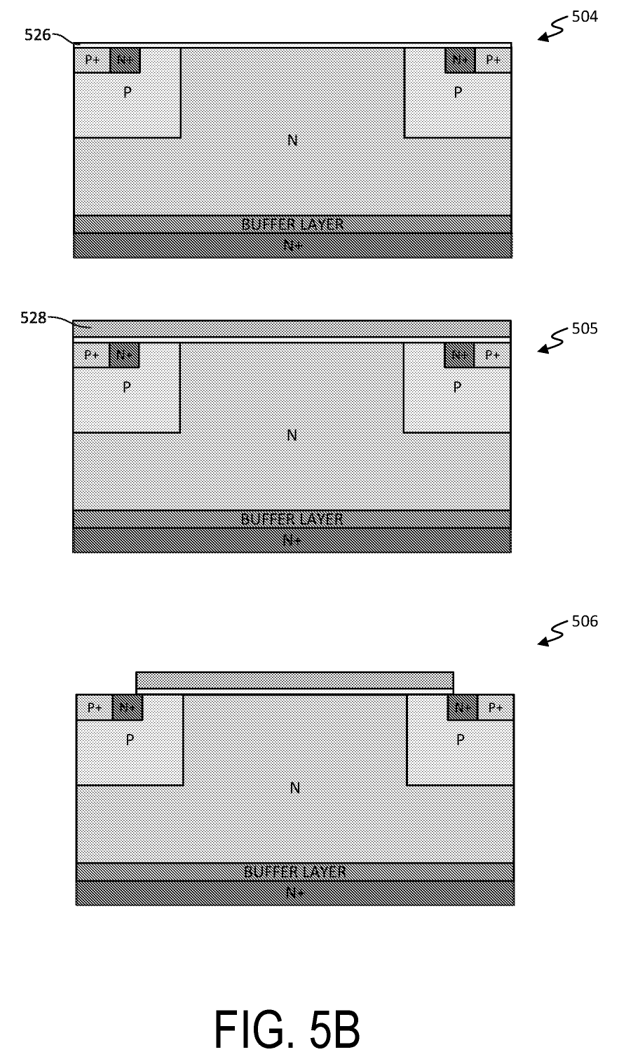

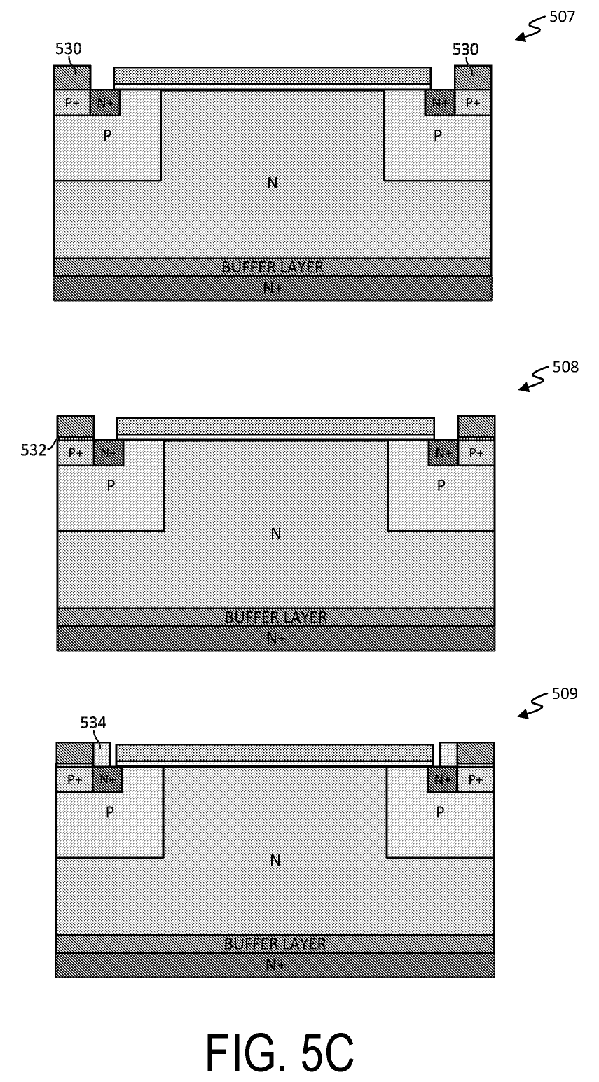

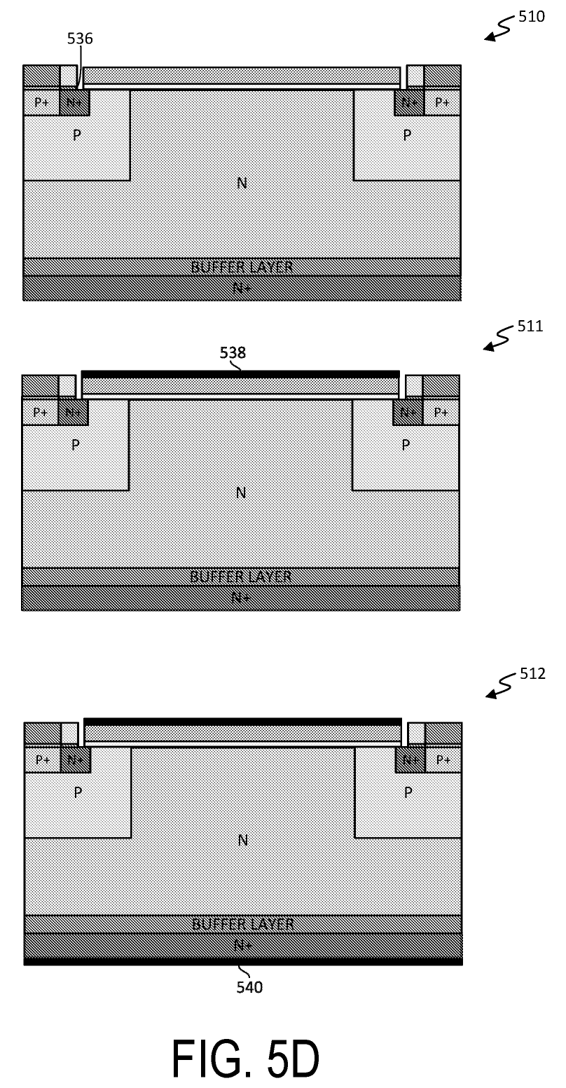

FIGS. 5A-5D illustrates a flow for manufacturing a transistor with sectioned source contacts for improved diode performance, in accordance with any of the examples disclosed herein.

In phase 501, a substrate 513 is provided. The substrate 513 may include an N-doped region 514, a buffer layer 515 (that is more heavily doped than N-doped region 514), and an N+ doped region 516 that is more heavily doped than the buffer layer 515. In some instances, the substrate 513 may be included on a wafer comprising silicon or silicon carbide. In various examples, the regions 514 or 516 of the original wafer may have a greater thickness than that shown and may be reduced to the desired size via any suitable method (e.g., etching, grinding, or other method). The thickness or doping concentration of the various substrate layers may be based on the voltage rating specified for the transistor being formed.

In phase 502, P-wells 518 are formed within the substrate 513. For example, a mask may be applied to the top of the substrate 513 and then a P-type dopant (e.g., aluminum or boron) may be implanted or diffused into the substrate 513 to form the P-wells 518.

In phase 503, another mask is applied and an N-type dopant (e.g., phosphorous, arsenic, antimony) is implanted or diffused to form N+ doped regions 520 within the P-wells 518. In some examples, the doped regions 520 have substantially the same concentration of dopants as the N+ doped region 516, though in other examples, the concentration of these respective regions may vary. The N+ doped region 516 and the N+ doped regions 520 may have higher dopant concentrations than the N-doped region 514 (e.g., such that the resistivity in these regions is very low), as these regions will interface with the drain and source contacts.

Another mask is applied and a P-type dopant is implanted or diffused to form P+ doped regions 522. The P+ doped regions 522 have a higher concentration of P-type dopants than the P-wells 518. The doping concentration in the P+ doped regions 522 may also be very high as these regions are to interface (e.g., contact) the source contacts and thus an ohmic contact is desired.

At phase 504 of FIG. 5B, an oxide layer 526 is formed (e.g., grown through thermal oxidation, deposition, or other method) over the top surfaces of the substrate 513, P-wells 518, N+ doped regions 520, and P+ doped regions 522. The oxide material may include, e.g., silicon oxide or hafnium oxide.

At phase 505, a gate material 528 is formed on the oxide layer 526 (e.g., through deposition). The gate material may comprise, e.g., polycrystalline silicon.

At phase 506, portions of the gate material 528 and the oxide layer 526 are removed (e.g., etched away) to form a gate with underlying oxide layer material between the gate and the substrate.

At phase 507 of FIG. 5C, a mask is applied and a conductive material is deposited to form first sections 530 of the source contacts. In some examples, the conductive material may be a metal alloy comprising aluminum and titanium. In another example, a thin layer of titanium may be deposited and then a thicker layer of aluminum may be deposited. In other examples, any suitable conductive material (e.g., suitable to result in an ohmic contact with the P+ region) may be used to form the first sections 530. At phase 508, an annealing process is performed and a silicide 532 is formed between the first section 530 and the P+ region.

At phase 509, a mask is applied and a second conductive material is deposited to form second sections 534 of the source contacts. In various examples, the second conductive material may include nickel, a nickel alloy (e.g., including vanadium), or other suitable conductive material (e.g., suitable to result in an ohmic contact with the N+ region).

At phase 510 of FIG. 5D, an annealing process is performed and a silicide 536 is formed between the second sections 534 and the N+ regions. In other examples, one annealing process may be performed to form silicide 532 and silicide 536.

At 511, a mask is applied and a gate contact material 538 is deposited on the gate. At 512, a drain contact material 540 is deposited on the N+ region 516.

Although not shown, after the drain, source, and gate contacts are formed, a plurality of wires may be formed to connect the drain, source, and gate contacts to respective pins of a semiconductor device package.

The examples described herein may be adapted to any suitable transistor architecture, such as P-type transistors (e.g., MOSFETs), JFETs, JBS diode integrated MOSFETs, trench MOSFETs, or other suitable transistor that may function as a diode under the proper biasing conditions. Any of these transistors may have one or more source contacts that may be sectioned with different conductive materials as described herein. In some instances, a transistor may have more than one source contact and any one or more of the source contacts of the transistor may be sectioned as described herein.

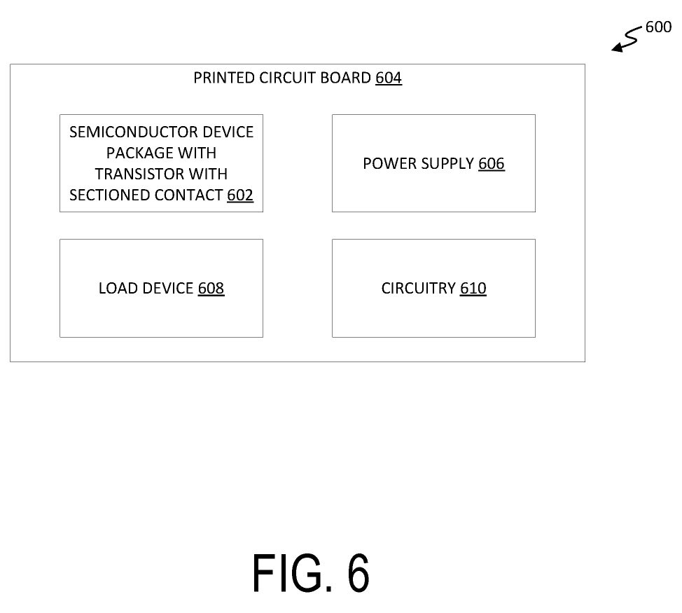

FIG. 6 illustrates a system 600 comprising a semiconductor device package 602 comprising a transistor with a sectioned source contact for improved diode performance, in accordance with any of the examples disclosed herein. The system 600 includes a printed circuit board 604 and various components connected to the printed circuit board. In the example depicted, these components include semiconductor device package 602, power supply 606, load device 608, and circuitry 610. The components may be coupled together in any suitable manner, such as through conductive traces on the semiconductor device package 602.

The semiconductor device package 602 may include any suitable semiconductor device package with a transistor with a sectioned source contact for improved diode performance, such as those described herein or variations thereof.

One or more power supplies 606 may provide electrical power to the components attached to the printed circuit board 604. A power supply 606 may include any suitable source of electrical power, such as, for example, a direct current power supply, an alternating current power supply, or a battery.

Load device 608 may comprise any suitable device connected to, powered by, or controlled by the semiconductor device package 602. For example, the load device 608 may include an electrical or mechanical device, such as a motor, solenoid, actuator, lighting device, battery pack, capacitor bank, power supply, inverter, heater, amplifier, or other suitable device.

Circuitry 610 may include any other suitable circuitry of the system 600, such as one or more integrated circuits, microcontrollers, processors, resistors, capacitors, diodes, transistors, inductors, transformers, switches, or other suitable circuitry.

In various examples, one or more of the illustrated components (or additional components) may be located off of the printed circuit board 604 and coupled to the printed circuit board 604 via any suitable connectors.

As used herein, the term “or” is intended to be inclusive rather than exclusive. That is, unless otherwise indicated or as would be apparent to one of skill in the art, the use of “or” is to be interpreted to mean “and/or.” For example, the phrase “A or B” is to be understood to mean “A, B, or both A and B.” The singular terms “a,” “an,” and “the” are intended to encompass their plural counterparts as well, unless it is clear from the context that a different interpretation is intended. Herein, when a list of items is preceded by phrases such as “at least one of” or “one or more of,” it is intended to allow for any combination of the listed elements.

The terms “above”, “over,” “under,” “between,” and “on,” as used herein, describe the relative positioning of components or materials. For instance, one layer being over or under another layer may encompass direct contact of the layers or the presence of one or more intermediate layers. Similarly, a layer described as being between two others may be in contact with both other layers or separated by one or more additional layers. Conversely, when a layer is “on” another layer, at least a portion of the layer is in direct physical contact with the underlying layer.

In the drawings, while some structural or method features may be shown in specific arrangements or orderings, such specific arrangements or orderings may be optional. In some examples, such features may be arranged in a different manner or order than shown in the drawings. Additionally, the inclusion of a structural or method feature in a particular drawing is not meant to imply that such feature is present in all examples, and, in some examples, such feature may not be included or may be combined with other features. Further, the various examples shown in the drawings are illustrative representations and may not be drawn to scale. In some instances, the same or similar reference numerals may be used to designate the same or similar features in different drawings.

Example 1 includes a transistor comprising a substrate comprising a P-type region and an N-type region within a doped well; and a source contact comprising a first section comprising a first metal over at least a portion of the P-type region; and a second section comprising a second metal over at least a portion of the N-type region.

Example 2 includes the subject matter of Example 1, and wherein the first section comprises aluminum.

Example 3 includes the subject matter of any of Examples 1 and 2, and wherein the first section comprises titanium.

Example 4 includes the subject matter of any of Examples 1-3, and wherein the second section comprises nickel.

Example 5 includes the subject matter of any of Examples 1-4, and wherein the second section comprises vanadium.

Example 6 includes the subject matter of any of Examples 1-5, and wherein the first section comprises a first layer comprising aluminum on a second layer comprising titanium.

Example 7 includes the subject matter of any of Examples 1-6, and further including a silicide between and in contact with the first section and the P-type region.

Example 8 includes the subject matter of any of Examples 1-7, and wherein the silicide comprises Ti₃SiC₂.

Example 9 includes the subject matter of any of Examples 1-8, and further including a silicide between and in contact with the second section and the N-type region.

Example 10 includes the subject matter of any of Examples 1-9, and wherein the silicide comprises Ni₂Si.

Example 11 includes the subject matter of any of Examples 1-10, and wherein a portion of the first section is over a portion of the N-type region.

Example 12 includes the subject matter of any of Examples 1-11, and wherein a portion of the second section is over a portion of the P-type region.

Example 13 includes a method for forming a transistor, the method comprising forming a doped well within a substrate; forming a P-type region and an N-type region within the doped well; and forming a source contact, the source contact comprising a first section comprising a first metal over at least a portion of the P-type region; and a second section comprising a second metal over at least a portion of the N-type region.

Example 14 includes the subject matter of Example 13, and wherein the first section comprises aluminum or titanium.

Example 15 includes the subject matter of any of Examples 13 and 14, and wherein the second section comprises nickel or vanadium.

Example 16 includes an apparatus comprising a semiconductor device package comprising a transistor, the transistor comprising a substrate comprising a P-type region and an N-type region within a doped well; and a source contact comprising a first section comprising a first metal over at least a portion of the P-type region; and a second section comprising a second metal over at least a portion of the N-type region.

Example 17 includes the subject matter of Example 16, and further including a printed circuit board, wherein the semiconductor device package is coupled to the printed circuit board.

Example 18 includes the subject matter of any of Examples 16 and 17, and further including an electrical or mechanical device coupled to the semiconductor device package through the printed circuit board.

Example 19 includes the subject matter of any of Examples 16-18, and wherein the first section comprises aluminum or titanium.

Example 20 includes the subject matter of any of Examples 16-19, and wherein the second section comprises nickel or vanadium.

While the concepts of the present disclosure are susceptible to various modifications and alternative forms, specific examples thereof have been shown in the drawings and described herein in detail. However, the concepts of the present disclosure are not limited to the particular forms disclosed, but on the contrary, all modifications, equivalents, and alternatives consistent with the present disclosure and the appended claims are also covered. Moreover, all examples described herein may be combined in any manner.

1. A transistor comprising:
a substrate comprising a P-type region and an N-type region within a doped well; and
a source contact comprising:
a first section comprising a first metal over at least a portion of the P-type region; and
a second section comprising a second metal over at least a portion of the N-type region.

2. The transistor of claim 1, wherein the first section comprises aluminum.

3. The transistor of claim 2, wherein the first section comprises titanium.

4. The transistor of claim 1, wherein the second section comprises nickel.

5. The transistor of claim 4, wherein the second section comprises vanadium.

6. The transistor of claim 1, wherein the first section comprises a first layer comprising aluminum on a second layer comprising titanium.

7. The transistor of claim 1, further comprising a silicide between and in contact with the first section and the P-type region.

8. The transistor of claim 7, wherein the silicide comprises Ti₃SiC₂.

9. The transistor of claim 1, further comprising a silicide between and in contact with the second section and the N-type region.

10. The transistor of claim 9, wherein the silicide comprises Ni₂Si.

11. The transistor of claim 1, wherein a portion of the first section is over a portion of the N-type region.

12. The transistor of claim 1, wherein a portion of the second section is over a portion of the P-type region.

13. A method for forming a transistor, the method comprising:
forming a doped well within a substrate;
forming a P-type region and an N-type region within the doped well; and
forming a source contact, the source contact comprising:
a first section comprising a first metal over at least a portion of the P-type region; and
a second section comprising a second metal over at least a portion of the N-type region.

14. The method of claim 13, wherein the first section comprises aluminum or titanium.

15. The method of claim 13, wherein the second section comprises nickel or vanadium.

16. An apparatus comprising:
a semiconductor device package comprising a transistor, the transistor comprising:
a substrate comprising a P-type region and an N-type region within a doped well; and
a source contact comprising:
a first section comprising a first metal over at least a portion of the P-type region; and
a second section comprising a second metal over at least a portion of the N-type region.

17. The apparatus of claim 16, further comprising a printed circuit board, wherein the semiconductor device package is coupled to the printed circuit board.

18. The apparatus of claim 17, further comprising an electrical or mechanical device coupled to the semiconductor device package through the printed circuit board.

19. The apparatus of claim 16, wherein the first section comprises aluminum or titanium.

20. The apparatus of claim 16, wherein the second section comprises nickel or vanadium.
